(19) United States
(12) Patent Application Publication
(10) Pub. No.: US 2014/0027823 A1
(43) Pub. Date: Jan. 30, 2014

(54) METHOD FOR FORMING THIN METAL COMPOUND FILM AND SEMICONDUCTOR STRUCTURE WITH THIN METAL COMPOUND FILM

(71) Applicant: NATIONAL APPLIED RESEARCH LABORATORIES, (US)

(72) Inventors: Yao-Jen Lee, Kaohsiung City (TW); Fu-Kuo Hsueh, Hsinchu (TW); Po-Jung Sung, Hsinchu (TW); Da-Wei Heh, New Taipei City (TW); Fu-Ju Hou, Hsinchu (TW); Chih-Hung Lo, Hsinchu (TW); Hsiu-Chih Chen, Hsinchu City (TW)

(73) Assignee: NATIONAL APPLIED RESEARCH LABORATORIES, Taipei City (TW)

(21) Appl. No.: 13/735,551

(22) Filed: Jan. 7, 2013

(30) Foreign Application Priority Data
Jul. 26, 2012 (TW) 101126956

(51) Int. Cl. H01L 29/40

(52) U.S. Cl. CPC H01L 29/401; H01L 29/40
USPC 257/288; 438/660

(57) ABSTRACT

A method for forming a metal compound film includes: providing a substrate structure; forming a first metal layer on the substrate structure; performing a first microwave annealing process to conduct a reaction between the first metal layer and the substrate structure so as to form a first polycrystalline film of a metal compound; and performing a second microwave annealing process to transform the first polycrystalline film into a second polycrystalline film of the metal compound with an enlarged grain size, wherein a microwave power output used in the second microwave annealing process is higher than that used in the first microwave annealing process.

### BACKGROUND OF THE INVENTION

1. Field of the Invention

The present invention relates to a method for forming a thin metal compound film, and more particularly, to a method for forming a thin metal compound film in a semiconductor device. The present invention also relates to a semiconductor structure having a thin metal compound film.

2. Description of Related Art

The miniaturization of a semiconductor device inherently leads to an increase in sheet resistance of the device. Thus production of a semiconductor device, such as a metal-oxide-semiconductor field effect transistor (MOSFET), with deep submicron meter size faces a bottleneck in miniaturization due to unsatisfactory performance.

In a common process for fabricating a semiconductor chip, a self-align silicide (SALICIDE) process is used to form metal silicide films on gate and source/drain regions of a MOSFET. The conventional SALICIDE process involves two stages of rapid thermal annealing (RTA). The first stage is performed with an RTA tool by heating the semiconductor substrate with gate, source and drain structures at an ambient temperature in a range of 240° C.˜300° C. while heating the semiconductor substrate at an ambient temperature in a higher range of 400° C.˜600° C. in the second stage. As known to those skilled in the art, high-temperature annealing is adverse to the fabrication of a MOSFET with deep submicron meter size as metal silicide films in a high sheet resistance phase, e.g. NiSi₂, would be rendered. Moreover, since high-temperature annealing is likely to lead to undesired diffusion in the metal silicide film, it is hard to control the thickness of the metal silicide film, for example to a level below 15 nanometers. As a result, the performance of the device cannot be further improved.

Therefore, there is a need to develop a method capable of forming an extremely thin metal compound film with reduced sheet resistance so as to provide a semiconductor device with an extremely thin metal compound film with reduced sheet resistance.

### SUMMARY OF THE INVENTION

In accordance with an aspect of the present invention, a method for forming an extremely thin metal film with low sheet resistance in a semiconductor device is provided in order to enhance the performance of the semiconductor device. In an embodiment, a substrate structure is provided. Then a first metal layer is formed on the substrate structure. After that, a first microwave annealing (MWA) process is performed to conduct a reaction between the first metal layer and the substrate structure so as to form a first polycrystalline film of a metal compound. Finally, a second MWA process is performed to transform the first polycrystalline film into a second polycrystalline film of the metal compound with an enlarged grain size, wherein a microwave power output used in the second microwave annealing process is higher than that used in the first microwave annealing process.

In one embodiment of the present invention, the substrate structure includes a source/drain region and the reaction is conducted between the source/drain region and the first metal layer in direct contact with the source/drain region.

In one embodiment of the present invention, the substrate structure includes a gate region and the reaction is conducted between the gate region and the first metal layer in direct contact with the gate region.

In one embodiment of the present invention, the substrate is made of indium gallium arsenide, gallium arsenide, silicon, germanium, germanium-silicon, silicon-germanium, silicon doped with carbon, phosphorous, and/or boron, or germanium doped with carbon and/or tin.

In one embodiment of the present invention, the first metal layer is made of a metal selected from a group consisting of palladium, platinum, dysprosium, tantalum, ytterbium, nickel, titanium, cobalt, wolfram, and alloy thereof.

In one embodiment of the present invention, before performing the first microwave annealing process, forming a second metal layer on the first metal layer to protect the first metal layer, wherein the second metal layer is made of titanium or titanium oxide.

In one embodiment of the present invention, the second metal layer formed on the first metal layer is made of titanium or titanium oxide.

In one embodiment of the present invention, the microwave power output used in the first microwave annealing process ranges between 250 W and 600 W and the microwave power output used in the second microwave annealing process ranges between 1000 W and 2000 W, and the second polycrystalline film is a polycrystalline metal silicide layer or polycrystalline metal silicon germanide layer.

In one embodiment of the present invention, the first microwave annealing process is performed at an ambient temperature ranging between 180° C. and 240° C. while the second microwave annealing process is performed at an ambient temperature ranging between 300° C. and 390° C.

In one embodiment of the present invention, the first polycrystalline film has a thickness less than 8 nanometers, and the second polycrystalline film has a thickness ranging between 9 nanometers and 11 nanometers and has a sheet resistance ranging between 17 ohm./sq. and 22 ohm./sq.

In one embodiment of the present invention, the microwave power output of the first microwave annealing process ranges between 200 W and 500 W and that of the second microwave annealing process ranges between 550 W and 2000 W so as to form the second polycrystalline metal semiconductor film which is a polycrystalline metal germanide layer, a polycrystalline metal germanium silicide layer, or a polycrystalline metal germanium stannide layer.

In one embodiment of the present invention, the ambient temperature of the first microwave annealing process ranges between 140° C. and 200° C. while the ambient temperature of the second microwave annealing process ranges between 220° C. and 390° C.

In one embodiment of the present invention, the first polycrystalline film has a thickness less than 6 nanometers, and the second polycrystalline film has a thickness ranging between 6.5 nanometers and 10 nanometers and has a sheet resistance ranging between 17 ohm./sq. and 26 ohm./sq.

In one embodiment of the present invention, the microwave power output of the first microwave annealing process ranges between 250 W and 500 W and that of the second microwave annealing process ranges between 550 W and 2000 W so as to form the second polycrystalline metal semiconductor film which is a polycrystalline metal indium gallium arsenide layer or a polycrystalline metal gallium arsenide layer.

In one embodiment of the present invention, the ambient temperature of the first microwave annealing process ranges between 180° C. and 200° C. while the ambient temperature of the second microwave annealing process ranges between 220° C. and 390° C.

In one embodiment of the present invention, the first polycrystalline film has a thickness less than 6 nanometers, and the second polycrystalline film has a thickness ranging between 6.5 nanometers and 10 nanometers and has a sheet resistance ranging between 17 ohm./sq. and 26 ohm./sq.

In one embodiment of the present invention, a microwave frequency used in each of the first microwave annealing process and the second microwave annealing process ranges between 900 MHz and 150 GHz, and an annealing time used in each of the first microwave annealing process and the second microwave annealing process ranges between 1 second and 60 minutes.

In accordance with another aspect, the present invention provides a semiconductor structure with improved performance, which is produced by the method according to the present invention and includes the substrate structure formed thereon a gate region and the source/drain region. The semiconductor structure further includes the second polycrystalline film of the metal compound formed on the source/drain region of the substrate structure and having a thickness in a range of 6.5 nanometers to 11 nanometers and with a sheet resistance in a range of 17 ohm./sq. to 26 ohm./sq.

In one embodiment of the present invention, the second polycrystalline film is a polycrystalline metal silicide layer or a polycrystalline metal silicon germanide layer with a thickness in a range of 9 nanometers to 11 nanometers and with a sheet resistance in a range of 17 ohm./sq. to 22 ohm./sq.

In one embodiment of the present invention, the second polycrystalline film is a polycrystalline metal indium gallium arsenide layer or a polycrystalline metal gallium arsenide layer with a thickness in a range of 6.5 nanometers to 10 nanometers and with a sheet resistance in a range of 17 ohm./sq. to 26 ohm./sq.

In accordance with a further aspect, a semiconductor device structure produced by the method according to the present invention includes the substrate structure formed thereon the gate structure and a source/drain region. The semiconductor structure further includes the second polycrystalline film of the metal compound formed on the gate region of the substrate structure and having a thickness in a range of 6.5 nanometers to 11 nanometers and a sheet resistance in a range of 17 ohm./sq. to 26 ohm./sq.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1 to 6 are cross-sectional views, combined to illustrate a method for forming a metal compound film in a semiconductor device in accordance with an embodiment of the present invention.

### DESCRIPTION OF EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

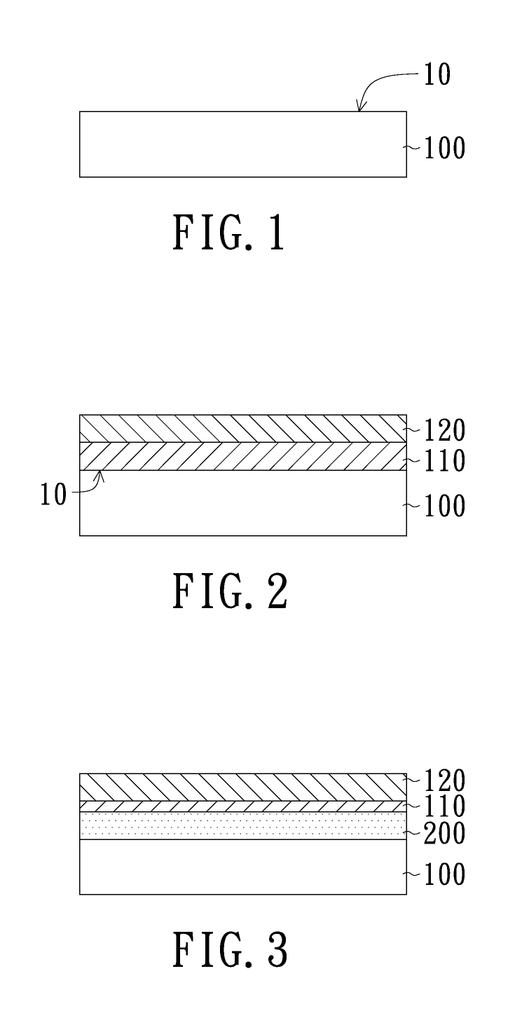

With reference to FIGS. 1 to 6, a method for forming a semiconductor structure having a metal compound in accordance with an embodiment of the present invention and the resulting semiconductor structure are schematically illustrated. Firstly, a first metal layer 110 is deposited on a surface 10 of a substrate 100. In this embodiment, before the SALICIDE process, the surface 10 of the substrate 100 has been formed thereon a gate region 40, a source/drain region 50 and shallow trench isolations 60 (FIGS. 1 and 6). The first metal layer 110 is then directly deposited on the gate region and the source/drain regions. Electronic gun (E-gun) or physical vapor deposition (PVD) may be used to deposit the first metal layer 110 on the substrate 100, for example up to a thickness of about 15 nanometers. The material of the substrate, for example, may be indium gallium arsenide, gallium arsenide, silicon, germanium, germanium-silicon, silicon-germanium, silicon doped with carbon, phosphorous and/or boron, or germanium doped with carbon and/or tin, etc. The material of the first metal layer 110, for example, may be palladium, platinum, dysprosium, tantalum, ytterbium, nickel, titanium, cobalt, wolfram, or a alloy formed thereof. Furthermore, as a protection layer, a second metal layer 120 is deposited on the first metal layer 110 in order to prevent the first metal layer 110 from oxygen pollutants in subsequent steps. The second metal layer 120 has a thickness of about 15 nanometers and, for example, may be made of titanium or titanium oxide.

Then, two-stage annealing is performed with a microwave generator (not shown) for forming the metal compound films. Referring to FIG. 3, at the first stage, a low-power microwave annealing (MWA) process is performed under a microwave power output in a range of 250˜600 Watts, a microwave frequency in a range of 900 MHz·150 GHz, and an annealing time in a range of 1 second to 60 minutes. In the embodiment, the low-power microwave annealing is conducted to induce a chemical reaction between the first metal layer 110 and the surface of the gate region and the source/drain region of the substrate 100. At the low temperature range of 180° C. to 240° C., a first polycrystalline film 200 of metal semiconductor compound, e.g. metal silicide, is formed. Provided that the substrate 100 is a silicon substrate or a silicon-germanium substrate, and the first metal layer is 110 is a nickel or titanium layer, for example, a polycrystalline nickel silicide (NiSi), nickel silicon germanide (NiSiGe) or titanium silicide (TiSi) layer will be formed as the first polycrystalline film 200. Due to the low-temperature feature, the molecule diffusion in the first polycrystalline film 200 is confined, so the resulting polycrystalline metal semiconductor film can be controlled to have a small grain size and a small film thickness less than 8 nm as well as low sheet resistance in a range of 140 ohm./sq. to 220 ohm./sq.

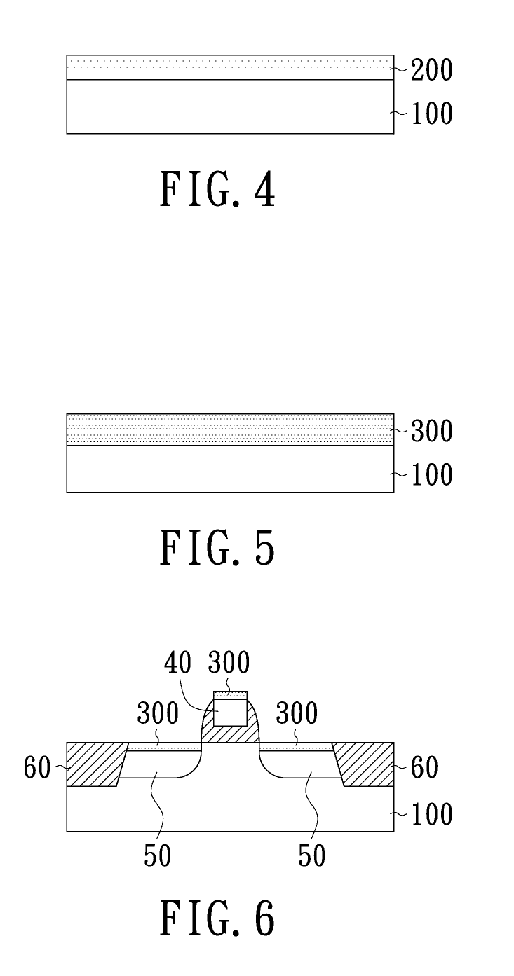

After the first MWA process, an etching process is performed to remove the unreacted first metal layer 110, if any, and the second metal layer 120 serving as the protection layer. The etching process may be performed by wet etching with a mixture of sulfuric acid and hydrogen peroxide or a mixture of ammonium hydroxide and hydrogen peroxide, for example, to selectively etch off the undesired layers, as shown in FIG. 4.

At the second stage, a high-power MWA process is performed under a microwave power output in a range of 1000˜2000 Watts. Meanwhile, a microwave frequency and an annealing time of the second MWA stage may be the same as those used in the first MWA process. By way of the high-power microwave annealing, the first polycrystalline film 200 with the small grain size can be transformed into a second polycrystalline film 300 of metal semiconductor compound with a bigger grain size. For example, a nickel silicide film is formed in NiSi phase, whose sheet resistance is at a level in a range of 17 ohm./sq. to 22 ohm./sq.

Even though the second-stage MWA process is conducted with a relatively high power, the ambient temperature is merely in a range of 300° C. to 390° C., so the molecule diffusion effect of the metal semiconductor compound film is not significant. Thus the thickness of the second polycrystalline film 300 can be easily controlled in a range of 9˜11 nanometers. Also due to the moderate temperature raise, the second polycrystalline film 300 remains in a low-sheet resistance phase, e.g. the NiSi phase, rather than being transformed into a high-sheet resistance phase, e.g. a NiSi₂ phase.

The resulting semiconductor structure is schematically shown in FIG. 6 which includes the polycrystalline metal semiconductor film 300 formed on the substrate 100 with the gate structure 40, the source/drain regions 50, and the shallow trench isolations 60. The polycrystalline metal semiconductor film 300 produced according to the present invention may have a thickness as small as in a range between 9 nm and 11 nm and a sheet resistance as low as in a range between 17 ohm./sq. and 22 ohm./sq. In the above embodiment, the polycrystalline metal semiconductor film 300 is formed on the gate structure 40 and the source/drain regions 50; however, the polycrystalline metal semiconductor film 300 may be formed on one of the gate structure 40 and the source/drain regions 50 because of different structures or materials of the semiconductor device.

With the changes of the materials for forming the semiconductor structure, alternative conditions may be applied. For example, provided that the substrate is made of germanium, germanium-silicon or germanium-tin, the microwave power output is desirably changed to a range between 250 W and 500 W, and the ambient temperature ranges between 140° C. and 200° C. in order to form the first polycrystalline film 200 with a thickness less than 6 nanometers. Subsequently, the second MWA process is performed with the microwave power output in a range of 550 W and 2000 W at an ambient temperature in a range of 220° C. and 390° C. so as to form the second polycrystalline film 300 with a bigger grain size than that of the first polycrystalline film 200. The resulting second polycrystalline film 300, for example, may be a polycrystalline nickel germanide (NiGe), titanium-germanium silicide (TiGeSi) or cobalt-germanium tinide (CoGeSn) layer, and has a thickness in a range between 6.5 nm and 10 nm and a sheet resistance in a range between 17 ohm./sq. and 26 ohm./sq.

Alternatively, the substrate may also be an indium gallium arsenide or gallium arsenide substrate. The first MWA process is performed with a microwave power output ranging between 250 W and 500 W at an ambient temperature ranging between 180° C. and 200° C. so as to form the first polycrystalline film 200 with a thickness less than 6 nanometers. Then the second MWA process is performed with the microwave power output in a range of 550 W and 2000 W at an ambient temperature in a range of 220° C. and 390° C. in order to form the second polycrystalline film 300 with a grain size bigger than that of the first polycrystalline film 200. When the substrate is an indium gallium arsenide substrate or a gallium arsenide substrate, the resulting second polycrystalline film 300 is a polycrystalline nickel-indium gallium arsenide (Ni—InGaAs) or titanium-gallium arsenide layer. In this embodiment, the polycrystalline film 300 can also be made to have a thickness in a range of 6.5˜10 nm and a sheet resistance in a range of 17˜26 ohm./sq.

According to the present invention, two microwave annealing processes are used to form an extremely thin metal semiconductor compound film with low sheet resistance. It is particularly advantageous over the high-temperature RTA processes for producing a small-size semiconductor device, such as a MOSEFT with deep submicron meter size, with improved performance.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

1. A method for forming a metal compound film, comprising:
providing a substrate structure;
forming a first metal layer on the substrate structure;
performing a first microwave annealing process to conduct a reaction between the first metal layer and the substrate structure so as to form a first polycrystalline film of a metal compound; and
performing a second microwave annealing process to transform the first polycrystalline film into a second polycrystalline film of the metal compound with an enlarged grain size, wherein a microwave power output used in the second microwave annealing process is higher than that used in the first microwave annealing process.

2. The method according to claim 1, wherein the substrate structure includes a source/drain region and the reaction is conducted between the source/drain region and the first metal layer in direct contact with the source/drain region.

3. The method according to claim 1, wherein the substrate structure includes a gate region and the reaction is conducted between the gate region and the first metal layer in direct contact with the gate region.

4. The method according to claim 1, wherein the substrate is made of indium gallium arsenide, gallium arsenide, silicon, germanium, germanium-silicon, silicon-germanium, silicon doped with carbon, phosphorous and/or boron, or germanium doped with carbon and/or tin.

5. The method according to claim 1, wherein the first metal layer is made of a metal selected from a group consisting of palladium, platinum, dysprosium, tantalum, ytterbium, nickel, titanium, cobalt, wolfram, and alloy thereof.

6. The method according to claim 1, further comprising, before performing the first microwave annealing process, forming a second metal layer on the first metal layer to protect the first metal layer, wherein the second metal layer is made of titanium or titanium oxide.

7. The method according to claim 1, wherein the microwave power output used in the first microwave annealing process ranges between 250 W and 600 W and the microwave power output used in the second microwave annealing process ranges between 1000 W and 2000 W, and the second polycrystalline film is a polycrystalline metal silicide layer or polycrystalline metal silicon germanide layer.

8. The method according to claim 7, wherein the first microwave annealing process is performed at an ambient temperature ranging between 180° C. and 240° C. while the second microwave annealing process is performed at an ambient temperature ranging between 300° C. and 390° C.

9. The method according to claim 7, wherein the first polycrystalline film has a thickness less than 8 nanometers, and the second polycrystalline film has a thickness ranging between 9 nanometers and 11 nanometers and has a sheet resistance ranging between 17 ohm./sq. and 22 ohm./sq.

10. The method according to claim 1, wherein the microwave power output of the first microwave annealing process ranges between 200 W and 500 W and that of the second microwave annealing process ranges between 550 W and 2000 W so as to form the second polycrystalline metal semiconductor film which is a polycrystalline metal germanide layer, a polycrystalline metal germanium silicide layer, or a polycrystalline metal germanium stannide layer.

11. The method according to claim 10, wherein the ambient temperature of the first microwave annealing process ranges between 140° C. and 200° C. while the ambient temperature of the second microwave annealing process ranges between 220° C. and 390° C.

12. The method according to claim 10, wherein the first polycrystalline film has a thickness less than 6 nanometers, and the second polycrystalline film has a thickness ranging between 6.5 nanometers and 10 nanometers and has a sheet resistance ranging between 17 ohm./sq. and 26 ohm./sq.

13. The method according to claim 1, wherein the microwave power output of the first microwave annealing process ranges between 250 W and 500 W and that of the second microwave annealing process ranges between 550 W and 2000 W so as to form the second polycrystalline metal semiconductor film which is a polycrystalline metal indium gallium arsenide layer or a polycrystalline metal gallium arsenide layer.

14. The method according to claim 13, wherein the ambient temperature of the first microwave annealing process ranges between 180° C. and 200° C. while the ambient temperature of the second microwave annealing process ranges between 220° C. and 390° C.

15. The method according to claim 13, wherein the first polycrystalline film has a thickness less than 6 nanometers, and the second polycrystalline film has a thickness ranging between 6.5 nanometers and 10 nanometers and has a sheet resistance ranging between 17 ohm./sq. and 26 ohm./sq.

16. The method according to claim 1, wherein a microwave frequency used in each of the first microwave annealing process and the second microwave annealing process ranges between 900 MHz and 150 GHz, and an annealing time used in each of the first microwave annealing process and the second microwave annealing process ranges between 1 second and 60 minutes.

17. A semiconductor structure produced by the method according to claim 2, comprising:
the substrate structure formed thereon a gate region and the source/drain region; and
the second polycrystalline film of the metal compound formed on the source/drain region of the substrate structure and having a thickness in a range of 6.5 nanometers to 11 nanometers and a sheet resistance in a range of 17 ohm./sq. to 26 ohm./sq.

18. The semiconductor structure according to claim 17, wherein the second polycrystalline film is a polycrystalline metal silicide layer or polycrystalline metal silicon germanide layer with a thickness in a range of 9 nanometers to 11 nanometers and a sheet resistance in a range of 17 ohm./sq. to 22 ohm./sq.

19. The semiconductor structure according to claim 17, wherein the second polycrystalline film is a polycrystalline metal indium gallium arsenide layer or a polycrystalline metal gallium arsenide layer with a thickness in a range of 6.5 nanometers to 10 nanometers and with a sheet resistance in a range of 17 ohm./sq. to 26 ohm./sq.

20. A semiconductor structure produced by the method according to claim 3, comprising:
the substrate structure formed thereon the gate region and a source/drain region; and
the second polycrystalline film of the metal compound formed on the gate region of the substrate structure and having a thickness in a range of 6.5 nanometers to 11 nanometers and a sheet resistance in a range of 17 ohm./sq. to 26 ohm./sq.
